(19) United States
(12) Patent Application Publication
(10) Pub. No.: US 2009/0286178 A1
(43) Pub. Date: Nov. 19, 2009

(54) PROCESS FOR PRODUCING RESIST COMPOSITION, FILTERING APPARATUS, RESIST COMPOSITION APPLICATOR, AND RESIST COMPOSITION

(76) Inventors: Masaaki Muroi, Kawasaki-shi (JP); Hirokazu Ozaki, Kawasaki-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/995,818

(22) PCT Filed: Jul. 12, 2006
(86) PCT No.: PCT/JP2006/313852

§ 371 Date: Jan. 15, 2008

(30) Foreign Application Priority Data
Jul. 19, 2005 (JP) 2005-208543

(51) Int. Cl. G03F 7/004; B01D 61/14; B01D 61/58; B05C 11/00; B01D 71/32; B01D 71/56; B01D 71/26

(52) U.S. Cl. 430/270.1; 210/321.6; 210/252; 118/610

(57) ABSTRACT

A process for producing a resist composition that yields a resist composition in which the occurrence of defects has been suppressed, a filtering apparatus that can be used favorably within the production process, a resist composition applicator that is fitted with the filtering apparatus, and a resist composition in which the level of defects has been suppressed. This composition is obtained by passing a resist composition, which is obtained by dissolving a resin component that displays changed alkali solubility under the action of acid and an acid generator component that generates acid upon exposure in an organic solvent, through a filter equipped with a polyethylene hollow thread membrane.

### TECHNICAL FIELD

The present invention relates to a process for producing a resist composition, a filtering apparatus, a resist composition applicator, and a resist composition.

Priority is claimed on Japanese Patent Application No. 2005-208543, filed Jul. 19, 2005, the content of which is incorporated herein by reference.

### BACKGROUND ART

Photolithography techniques include processes in which, for example, a resist film formed from a resist material is formed on top of a substrate, the resist film is selectively irradiated with light or an electron beam or the like through a photomask in which a predetermined pattern has been formed, and a developing treatment is then conducted, thereby forming a resist pattern of the prescribed shape in the resist film. Resist materials in which the exposed portions change to become soluble in the developing liquid are termed positive materials, whereas resist materials in which the exposed portions change to become insoluble in the developing liquid are termed negative materials. Resist materials are usually dissolved in an organic solvent, and used in the form of resist solutions for the formation of resist patterns.

In recent years, in the production of semiconductor elements and liquid crystal display elements, advances in lithography techniques have lead to rapid progress in the field of miniaturization. Typically, these miniaturization techniques involve shortening the wavelength of the exposure light source. Conventionally, ultraviolet radiation typified by g-line and i-line radiation has been used. However, nowadays KrF excimer lasers (248 nm) have been introduced, and ArF excimer lasers (193 nm) are also starting to be introduced. Furthermore, investigations are also being conducted into the use of even shorter wavelengths such as F₂ excimer lasers (157 nm), extreme ultra violet radiation (EUV), electron beams (EB), and X-rays and the like.

Furthermore, in order to reproduce patterns of very fine dimensions, resist materials with high resolution are required. Chemically amplified resist compositions, which contain a base resin and an acid generator that generates acid upon exposure, are used as these types of resist materials.

Currently, in those cases where a KrF excimer laser (248 nm) is used as the exposure light source, a polyhydroxystyrene (PHS) which exhibits a high degree of transparency relative to KrF excimer laser light, or a PHS-based resin in which the hydroxyl groups have been protected with acid-dissociable, dissolution-inhibiting groups, is typically used as the base resin for a chemically amplified resist. Furthermore, in those cases where an ArF excimer laser (193 nm) is used as the exposure light source, resins (acrylic resins) containing structural units within the principal chain that are derived from (meth)acrylate esters, which exhibit a high degree of transparency relative to ArF excimer laser light, are commonly used (for example, see patent reference 1).

However, when the types of resist materials described above are used, a problem arises in that the surface of the formed resist pattern tends to develop defects. These defects refer to general abnormalities detected, for example, by inspection of the developed resist pattern from directly above the resist pattern using a surface defect inspection device (brand name: KLA) from KLA Tencor Corporation. Examples of these abnormalities include post-developing scum (mainly undissolved residues and the like), foam, dust, color irregularities, and bridges across different portions of the resist pattern. Defects refer only to irregularities that occur at the resist surface (in the resist pattern surface) following developing, and are different from so-called pinhole defects that occur in the resist coating film prior to pattern formation.

Conventionally, these types of defects have caused few problems. However in recent years, with increasing demands for high-resolution resist patterns of 0.15 microns or smaller, improving the level of defects has become a significant problem.

Until now, most attempts to address this problem have focused mainly on the resist composition (the base resin, acid generator, and organic solvent and the like within the resist composition) (for example, see patent reference 2).

On the other hand, one cause of defects is the existence of solid foreign matter such as very fine particles within the solution-state resist composition (the resist solution). This foreign matter tends to develop over time within the resist solution, for example during storage of the resist composition in solution form, and can cause a deterioration in the storage stability of the resist. As a result, a multitude of methods have been proposed for improving the level of foreign matter.

Until now, in a similar manner to that described above for defects, attempts to reduce the quantity of this foreign matter have focused on the resist composition (for example, see patent reference 3).

Furthermore, patent reference 4 proposes a process for producing a resist composition using a closed system fitted with a filter, wherein the quantity of fine particles within the resist composition is reduced by circulating the resist composition.

Furthermore, patent reference 5 proposes a process for producing a resist composition in which the storage stability of the resist composition is improved by passing the composition through a filter having a positive zeta potential.

[Patent Reference 1]

Japanese Patent (Granted) Publication No. 2,881,969

[Patent Reference 2]

Japanese Unexamined Patent Application, First Publication No. 2001-56556

[Patent Reference 3]

Japanese Unexamined Patent Application, First Publication No. 2001-22072

[Patent Reference 4]

Japanese Unexamined Patent Application, First Publication No. 2002-62667

[Patent Reference 5]

Japanese Unexamined Patent Application, First Publication No. 2001-350266

### DISCLOSURE OF INVENTION

### Problems to be Solved by the Invention

However, when a chemically amplified resist is used as the resist material, the methods described above are unable to suppress the occurrence of defects to the level demanded by cutting-edge applications. For example, at the resist composition level, increasing the hydrophilicity of the base resin and thereby suppressing the occurrence of post-developing deposits is one possible method of reducing the level of defects. However, increasing the hydrophilicity of the base resin is usually accompanied by a deterioration in the lithography properties, meaning achieving a satisfactory improvement in the level of defects is impossible. Furthermore, methods such as those disclosed in the patent references 4 and 5, where the quantity of foreign matter is reduced by passing the resist solution through a filter, are also unable to achieve a satisfactory improvement in the level of defects.

The present invention takes the above circumstances into consideration, and has an object of providing a process for producing a resist composition that yields a resist composition in which the occurrence of defects has been suppressed, a filtering apparatus that can be used favorably within the production process, a resist composition applicator that is fitted with the filtering apparatus, and a resist composition in which the level of defects has been suppressed.

### Means for Solving the Problems

As a result of intensive investigation, the inventors of the present invention discovered that the above object could be achieved by passing the resist composition through a filter (f1) equipped with a polyethylene hollow thread membrane, and they were therefore able to complete the present invention.

In other words, a first aspect of the present invention is a process for producing a resist composition that includes a step (I) of passing a resist composition, which is obtained by dissolving a resin component (A) that displays changed alkali solubility under the action of acid and an acid generator component (B) that generates acid upon exposure in an organic solvent (S), through a filter (f1) equipped with a polyethylene hollow thread membrane.

Furthermore, a second aspect of the present invention is a filtering apparatus containing a filtering unit (F1), which has a filter (f1) equipped with a polyethylene hollow thread membrane, and is provided within the flow path for a resist composition obtained by dissolving a resin component (A) that displays changed alkali solubility under the action of acid and an acid generator component (B) that generates acid upon exposure in an organic solvent (S).

A third aspect of the present invention is a resist composition applicator that is fitted with a filtering apparatus according to the second aspect described above.

A fourth aspect of the present invention is a resist composition obtained using the process for producing a resist pattern according to the first aspect described above.

### EFFECTS OF THE INVENTION

According to the present invention, a process for producing a resist composition in which the occurrence of defects has been suppressed, a filtering apparatus that can be used favorably within the production process, a resist composition applicator that is fitted with the filtering apparatus, and a resist composition in which the level of defects has been suppressed are able to be provided.

### BRIEF DESCRIPTION OF THE DRAWINGS

FIG. 1 is a schematic illustration showing an embodiment of the filtering apparatus.

FIG. 2 is a graph showing a Zisman Plot.

FIG. 3 is a schematic illustration showing an embodiment of an applicator fitted with a filtering apparatus.

### DESCRIPTION OF THE REFERENCE SYMBOLS

1 Storage tank
2 First filtering unit 2a First filter
3 Filtrate storage tank
4 Second filtering unit 4a Second filter
5 Container
6 Pressurization pipe
7 Resist composition
8 Storage unit
9 Supply pipe
10 Reservoir tank
11 Pump
12 Filtering unit (F1) 12a Filter (f1)
13 Nozzle
14 Substrate
15 Support
16 Closed-base cylindrical body
17 Rotational axis
18 Coating unit

### BEST MODE FOR CARRYING OUT THE INVENTION

### Process for Producing Resist Composition and Filtering Apparatus

A process for producing a resist composition according to the present invention must include a step (I) of passing a resist composition, which is obtained by dissolving a resin component (A) that displays changed alkali solubility under the action of acid (hereafter referred to as the component (A)) and an acid generator component (B) that generates acid upon exposure (hereafter referred to as the component (B)) in an organic solvent (S) (hereafter referred to as the component (S)), through a filter (f1) equipped with a polyethylene hollow thread membrane.

Furthermore, a filtering apparatus of the present invention must contain a filtering unit (F1) having a filter (f1) equipped with a polyethylene hollow thread membrane provided within the flow path for the resist composition obtained by dissolving the component (A) and the component (B) in the component (S).

By adopting these types of configurations, techniques can be provided that yield resist compositions in which the occurrence of defects has been suppressed. As a result, excellent stability of the size of formed resist patterns can be achieved.

It is thought that the reasons for this effect include the fact that because the filter (f1) employs a hollow thread membrane, then compared with a commonly employed flat membrane filter (such as a flat filter or pleated filter or the like), the filter is less prone to deterioration in the foreign matter removal performance caused by rippling of the filter that can occur when the pressure acting on the membrane fluctuates during passage of the liquid through the filter, and the fact that because the filter is made from polyethylene, the foreign matter removal performance is superior to filters made from other materials (such as polypropylene).

Moreover, another possible reason that the above effect can be achieved is reflected in the fact that comparison of the makeup of the resist composition prior to, and then following, passage through the filter reveals minimal change in the composition. In other words, conventionally when a resist composition is passed through a filter, a problem arises in that solutes derived from the filter (including metal elements such as sodium, potassium, iron, calcium and aluminum, as well as nonvolatile components and chlorine and the like) are eluted into the resist composition. However in the present invention, the quantity of such solutes within the resist composition can be reduced. It is surmised that this effect is due to the fact that the filter (f1) exhibits excellent resistance to the component (S) and the like.

Furthermore, because the quantity of solutes originating from the filter can be reduced, the lifespan of the filter itself is very long. Furthermore, because the filter (f1) is a hollow thread membrane type filter, it exhibits excellent processing performance, enabling a large quantity of resist composition to be filtered within a short time period. As a result, the production efficiency is excellent. For these reasons, costs can also be reduced.

In the present invention, the term “filter” refers to a device that includes at least a porous membrane that allows passage of the resist composition, and a support member that supports the membrane. Examples of this type of filter include filters of various materials and pore sizes for filtering ultra pure water, high-purity pharmaceuticals and fine chemicals, manufactured and marketed by filter manufacturers such as Pall Corporation, Advantec Toyo Co., Ltd., Mykrolis Corporation, and KITZ Corporation. In the present invention, there are no particular restrictions on the configuration of the filter, provided it is equipped with a membrane (a hollow thread membrane in the case of the filter (f1)), and commonly used configurations such as disc type and cartridge type filters, in which the membrane is housed inside a container, can be used.

In the production process of the present invention, the “resist composition” passed through the filter includes not only resist compositions having the same solid fraction concentration as the product, but also so-called resist composition concentrates that have a higher solid fraction concentration than the product (for example, solid fraction concentrations within a range from approximately 8 to 15% by weight).

Furthermore, the term “filtration”, as used in relation to the present invention, describes not only the typically used chemical meaning of the term (“the passage of only the fluid phase [either gaseous or liquid] through a membrane or phase formed from a porous substance, thereby separating a semisolid phase or a solid from the fluid phase”, Encyclopedia Chimica, vol. 9, published Jul. 31, 1962, Kyoritsu Shuppan Co., Ltd.), but also those cases where a substance is simply “passed through a filter”, that is, cases where after passage of a substance through a membrane, a semisolid phase or solid material that has been trapped by the membrane may not necessarily be visible.

As follows is a description of an embodiment of the process for producing a resist composition and a filtering apparatus according to the present invention.

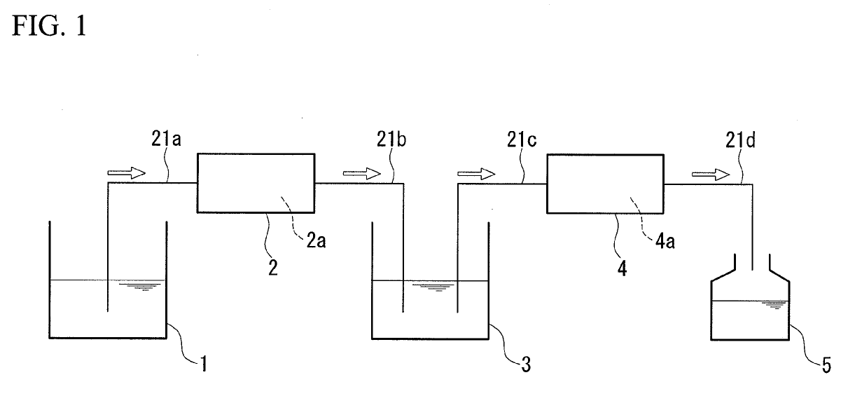

An embodiment of the filtering apparatus of the present invention is shown in FIG. 1.

This filtering apparatus includes a first filtering unit 2 equipped with a first filter 2a, and a second filtering unit 4 equipped with a second filter 4a.

Furthermore, the above filtering apparatus also contains a storage tank 1 for storing the resist composition prepared by dissolving the component (A) and the component (B) in the component (S), and a filtrate storage tank 3 that stores the resist composition that has passed through the first filtering unit 2. Moreover, the storage tank 1 and the first filtering unit 2, the first filtering unit 2 and the filtrate storage tank 3, and the filtrate storage tank 3 and the second filtering unit 4 are connected via flow passages 21a, 21b and 21c respectively. Furthermore, the second filtering unit 4 is connected to a flow passage 21d that feeds the resist composition that has passed through the second filtering unit 4 into a container 5.

In the present embodiment, at least one of the first filter 2a and the second filter 4a must be a filter (f1) equipped with a polyethylene hollow thread membrane.

By employing such a configuration, the resist composition passes, at least once, through the filter (f1). This enables a resist composition to be obtained in which the occurrence of defects has been suppressed.

When using this type of filtering apparatus, the resist composition can be produced in the manner described below.

First, a resist composition is prepared by dissolving the component (A) and the component (B) in the component (S). This resist composition is supplied from the storage tank 1 (the storage unit for the resist composition) to the first filtering unit 2. As a result, the resist composition passes through, and is filtered by, the first filter 2a contained within the first filtering unit 2, and then enters the filtrate storage tank 3.

Subsequently, the filtrate (the resist composition) is supplied from the filtrate storage tank 3 to the second filtering unit 4. As a result, the resist composition passes through, and is filtered by, the second filter 4a contained within the second filtering unit 4. Finally, the resulting filtrate (resist composition) enters the container 5 as a final product.

During this process, the step (I) may be conducted using the filter (f1) as the first filter 2a, and a post-filtering step then conducted using a filter (f2) equipped with a membrane formed from a material other than polyethylene as the second filter 4a. Furthermore, the step (I) may also be conducted using the filter (f1) as the second filter 4a, and a pre-filtering step conducted prior to this step using the filter (f2) as the first filter 2a.

Furthermore, both the first filter 2a and the second filter 4a may be filters (f1). In such cases, the composition can be easily passed twice or more through the filters (f1). If normal methods are used to form an apparatus in which the solution undergoing treatment (the resist composition) is passed through the above filters and the resulting filtrate is then recirculated and passed through the same filters a second time, then the resist composition can be easily passed through the filters a plurality of times.

Furthermore, if no pre-filtering or post-filtering step is conducted, and only the step (I) is conducted once, then the filter (f1) is used as the second filter 4a, and the resist composition is supplied directly from the storage tank 1 to the second filter 4a.

In the present invention, the step using the filter (f2) is not a necessity. However, conducting a step using the filter (f2) further enhances the effects of the present invention and is consequently preferred. In particular, conducting a pre-filtering step using the filter (f2) and then conducting the step (I) is preferred, as it enables the filtering burden placed on the filter (f1) to be reduced, and further enhances the defect reduction effect and the degree of reduction in the quantity of foreign matter.

There are no particular restrictions on the number of times the composition is passed through a single filter (the filter (f1) or filter (f2)), or on the types of filter (f2) that can be combined with the filter (f1), and these factors can be selected in accordance with the desired objectives.

[Filter (f1) Equipped with a Polyethylene Hollow Thread Membrane]

In the present invention, a filter (f1) equipped with a polyethylene hollow thread membrane must be used.

Examples of filters equipped with a hollow thread membrane include filters containing a plurality of hollow thread membranes bundled together and housed inside a container, such as those used in extracorporeal ultra filtration, precision filtration, reverse osmosis, artificial dialysis, and gas separation and the like. The hollow thread membranes used in these type of filters generally use polypropylene membranes. However, if a filter equipped with a polypropylene hollow thread membrane is used instead of the filter (f1), then the superior defect improvement effect observed using the filter (f1) is unobtainable.

The pore size of the membrane used in the filter (f1) can be specified within a desired range using the nominal values reported by the filter manufacturers. This desired range can be adjusted appropriately with due consideration of the productivity and the effects of the present invention, by altering the filtering unit combination (the combination of factors such as the filter configuration, the type of membrane, and the number of times the composition is passed through the membrane).

From the viewpoint of the effects obtained, the pore size of the membrane within the filter (f1) is preferably not more than 0.2 μm, even preferably not more than 0.1 μm, and is most preferably 0.04 μm or smaller.

However, if the pore size is too small, then the productivity (the throughput for the production and application of the resist composition) tends to fall, and consequently the lower limit for the pore size is preferably approximately 0.01 μm, and is even more preferably 0.02 μm or greater. If due consideration is given to the defect reduction effect, the foreign matter improvement effect, and the productivity, then the pore size of the membrane used in the filter (f1) is preferably within a range from 0.01 to 0.1 μm, even more preferably from 0.01 to 0.04 μm, and is most preferably from 0.01 to 0.02 μm.

The surface area (filtration area) and filtration pressure [differential pressure resistance] for the filter (f1), and the flow rate with which the resist composition passes through the filter (f1) are preferably adjusted in accordance with factors such as the quantity of the resist composition being processed, and there are no particular restrictions on these settings.

As the filter (f1), for example, samples provided by KITZ Corporation can be used.

[Filter (f2) Equipped with a Membrane Formed from a Material Other than Polyethylene]

There are no particular restrictions on the membrane formed from a material other than polyethylene, and the filters used in conventional filtration applications can be used.

As the filter (f2), the use of filters with a critical surface tension of at least 70 dyne/cm that have not been subjected to charge modification is preferred. These types of membranes provide a superior reduction in the level of defects, particularly in terms of suppressing fine scum and microbridges, and reducing the quantity of foreign matter. Furthermore, comparison of the resist composition prior to, and then following, passage through the filter reveals minimal variation in the makeup of the resist composition. As a result, a superior level of stability in the size of the formed resist pattern can also be obtained.

The “critical surface tension” is a property that is widely referred to as the “wetting characteristic” of a polymer surface, and refers to the surface tension (γc) of a solid.

Unlike a liquid, this γc value cannot be evaluated directly, and is instead determined in the manner described below, using the Young-Dupre formula and a Zisman plot that is described below.

γLV cosθ=γSV−γSL Young Dupre Formula

In this formula, θ represents the contact angle, S is a solid, L is a liquid, and V is a saturated vapor. When water is used as the liquid, θ is 90°, and when θ exceeds 90° the surface is hydrophobic, whereas surfaces in which θ is close to 0° are hydrophilic.

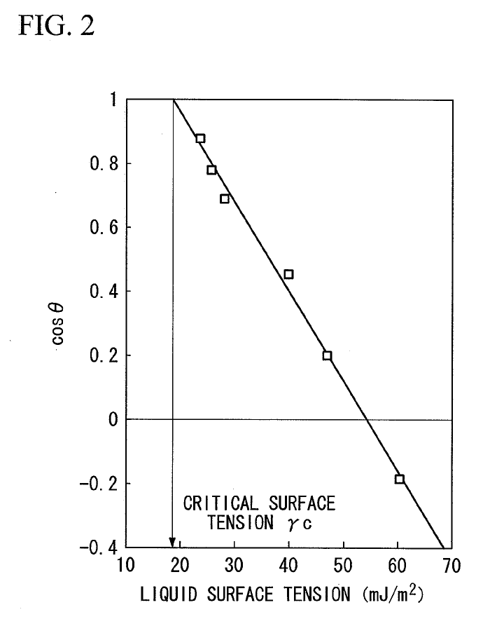

Zisman Plot (see FIG. 2): Using liquids with a variety of different surface tension values γLV, the contact angle θ is measured, and a plot is produced with γLV along the horizontal axis and cos θ along the vertical axis. As the value of γLV approaches the value of γSV of the solid surface, the value of 0 decreases, and at a certain value of γLV, the contact angle θ becomes 0°. This value of γLV for the liquid where θ=0 is defined as the solid surface tension, that is, the critical surface tension (γc).

The critical surface tension γc refers to the critical surface tension at the membrane, and is not the value for the polymer material (the material). In other words, the polymer material (the material), and the membrane of the filter prepared by processing the material to enable it to function as a filter (the medium) usually exhibit different γc values.

For materials (polymer materials) typically used in producing filters, examples of the γc values for the membrane (the processed membrane for use in a filter) (the medium), and the original polymer material prior to its use within the filter (prior to being processed for use within the filter) (the material) are listed below.

Nylon

For example in the case of nylon 66, the γc value for a membrane of nylon 66 within a filter (a medium) is 77 dyne/cm, whereas the γc value for typical nylon 66 that is not installed within a filter (a material) is 46 dyne/cm.

Polypropylene

The γc value for a membrane of polypropylene within a filter (a medium) is 36 dyne/cm. Polypropylene membranes include not only membranes of common polypropylene, but also membranes of high density polypropylene (HDPP) and ultra high molecular weight polypropylene (UPP).

Fluororesins

For example, in the case of polytetrafluoroethylene (PTFE), the γc value for a membrane of PTFE within a filter (a medium) is 28 dyne/cm, whereas the γc value for typical PTFE that is not installed within a filter (a material) is 18.5 dyne/cm.

This difference in critical surface tension values between the polymer material and the membrane used within the filter arises as a result of processing of the polymer material (the material) to enable its use within the filter.

Even with the same starting material, if the nature of the processing is altered, then the critical surface tension value will also differ. Accordingly, the critical surface tension for a filter membrane is preferably determined by confirming the nominal value or determining a measured value. Use of the nominal critical surface tension values provided by the filter manufacturers is the simplest option. On the other hand, a measured value for the critical surface tension can also be determined relatively easily by preparing a plurality of liquids with known surface tension values, and then dripping each of these liquids onto the target membrane, and determining the boundary between those liquids that penetrate the membrane under their own weight, and those liquids that do not penetrate.

The upper limit for the critical surface tension is preferably not more than 95 dyne/cm, as higher values can cause a deterioration in the defect reduction effect. Even more preferred critical surface tension values are within a range from at least 75 dyne/cm to not more than 90 dyne/cm, and the most desirable values are from at least 75 dyne/cm to not more than 80 dyne/cm.

“Charge modification” has the same meaning as the expression forced potential modification. Furthermore, the existence or absence of charge modification correlates with the zeta potential value, and the phrase “not subjected to charge modification” can also be interpreted as displaying a specific zeta potential in pH 7.0 distilled water.

The “zeta potential” is the electric potential of the diffuse ion layer generated around the periphery of a charged particle in a liquid. More specifically, if an ultra-fine powder displays a charge within a liquid, then an electrical double layer can be formed by oppositely charged ions which are electrostatically attracted to the powder in order to cancel out its charge. The potential at the outermost surface of this electrical double layer is the zeta potential. Measurement of the zeta potential is said to be effective in determining the surface structure of fine powders and fine particles.

As mentioned above, in this description, the simplified term “zeta potential” describes the “zeta potential in distilled water of pH 7.0”, and the numerical values for the zeta potential are the nominal values provided by the filter manufacturers. In this description, a membrane that “has not been subjected to charge modification” has a zeta potential within a range exceeding −20 mV but not more than 15 mV. In terms of maximizing the effects of the present invention, the zeta potential is preferably greater than −20 mV but not more than 10 mV, and even more preferably greater than −20 mV and less than 10 mV, and is most preferably a negative value (although greater than −20 mV).

This negative zeta potential is preferably not more than −5 mV (although greater than −20 mV), and is even more preferably within a range from −10 to −18 mV, and most preferably from −12 to −16 mV.

In this manner, by employing a membrane (a membrane that has not been subjected to charge modification) with a zeta potential exceeding −20 mV but not more than 15 mV, and in particular a membrane with a negative zeta potential, the level of defects, and in particular the level of fine scum and microbridges, can be reduced, and the quantity of foreign matter can also be improved. Furthermore, when a resist composition is filtered through such a membrane, the makeup of the composition displays minimal change following filtration, meaning a resist composition with excellent resist pattern size stability, which is resistant to variations in sensitivity and the resist pattern size, can be obtained.

In the present embodiment, the filter (f2) preferably uses a filter equipped with a nylon (polyamide resin) membrane and/or a filter equipped with a fluororesin membrane.

Examples of suitable nylons include nylon 6 and nylon 66.

Examples of suitable fluororesins include PTFE (polytetrafluoroethylene) and the like.

A nylon membrane is preferred in terms of achieving a critical surface tension of at least 70 dyne/cm, and a nylon membrane that has not been subjected to charge modification is particularly desirable.

Specific examples of filters equipped with a nylon membrane include the Ultipore N66 filter (a product name, manufactured by Pall Corporation, a flat membrane-type filter, zeta potential: approximately −12 to −16 mV), which is manufactured from nylon 66 that has not been subjected to charge modification, and the Ultipleat (a registered trademark) P-Nylon filter (a product name: manufactured by Pall Corporation, a flat membrane-type filter, zeta potential: approximately −12 to −16 mV, pore size: 0.04 μm), which is manufactured from nylon 66. Of these, the Ultipleat (a registered trademark) filter is preferred.

Specific examples of filters equipped with a fluororesin membrane include the Emflon filter (a product name: manufactured by Pall Corporation, a flat membrane-type filter, zeta potential: −20 mV, pore size: 0.05 μm), which is manufactured from polytetrafluoroethylene, and the FluoroLine filter (a product name: manufactured by Mykrolis Corporation, a flat membrane-type filter, pore size: 0.05 to 0.2 μm), which is also manufactured from polytetrafluoroethylene.

A filter equipped with a nylon membrane is preferred as the filter (f2) used in a pre-filtering step, as it yields improved effects for the present invention.

A filter equipped with a membrane formed from a fluororesin such as PTFE is preferred as the filter (f2) used in a post-filtering step, as it yields improved effects for the present invention.

The pore size of the membrane used in the filter (f2) can be set to a value within the desired range based on the nominal value provided by the filter manufacturer. By altering the filtering unit combination (the combination of factors such as the filter configuration, the type of membrane, and the number of times the composition is passed through the membrane), appropriate adjustments can be made to the productivity and the effects of the present invention.

From the viewpoint of the effects obtained, the pore size of the membrane within the filter (f2) is preferably not more than 0.2 μm, even preferably not more than 0.1 μm, and is most preferably 0.04 μm or less.

However, if the pore size is too small, then the productivity (the throughput for the production and application of the resist composition) tends to fall, and consequently the lower limit for the pore size is preferably approximately 0.01 μm, and is even more preferably 0.02 μm or greater. If due consideration is given to the defect reduction effect, the foreign matter improvement effect, and the productivity, then the pore size of the membrane used in the filter (f2) is preferably within a range from 0.01 to 0.1 μm, even more preferably from 0.02 to 0.1 μm, and is most preferably from 0.02 to 0.04 μm. In terms of achieving a favorable combination of effects and productivity, a pore size of approximately 0.04 μm is most preferred.

The surface area (filtration area) and filtration pressure [differential pressure resistance] for the filter (f2), and the flow rate with which the resist composition passes through the filter (f2) are preferably adjusted in accordance with factors such as the quantity of the resist composition being processed, and there are no particular restrictions on these settings. Accordingly, conventional conditions may be used.

In the present invention, the filtering apparatus is not limited to the embodiment shown in FIG. 1, and various different modes can be employed, provided the filter (f1) is provided within the flow path for the resist composition. For example, a third filtering unit may be provided downstream from the second filtering unit 4. In such a case, a pre-filtering step, the step (I), and a post-filtering step can be conducted, by passing the resist composition through a first filtering unit 2 containing a filter (f2) (for example, a filter equipped with a nylon membrane), a second filtering unit 4 containing the filter (f1), and a third filtering unit containing a filter (f2) (for example, a filter equipped with a PTFE membrane).

The filtering apparatus of the present invention can be installed, for example, within an applicator such as a spinner or coater-developer, as described below.

### [Resist Composition Applicator]

A resist composition applicator of the present invention is fitted with the filtering apparatus described above.

In this description, the term resist composition applicator is a comprehensive term that refers to an applicator fitted with the filtering apparatus of the present invention, and includes not only devices such as spinners that possess only an application function, but also applicators such as coater-developers that are integrated with another device such as a developer.

This type of applicator has a nozzle, and is usually configured so that the resist composition is supplied from this nozzle onto a wafer (a substrate), with the resist composition coating the surface of the wafer.

Accordingly, by incorporating the filtering apparatus of the present invention within an applicator described above, so that prior to supply from the nozzle to the wafer surface, the resist composition passes through the membrane of the filtering apparatus of the present invention, those substances within the resist composition that can cause defects, deterioration in the foreign matter characteristics, and deterioration in the storage stability as a resist solution are removed prior to supply of the resist composition to the wafer. As a result, a superior reduction in the level of defects, and particularly the level of fine scum and microbridges, and excellent stability in the resist pattern size can be achieved.

When an applicator is configured in this manner, the filter is preferably removable from the applicator. In other words, in the applicator fitted with a filtering apparatus, a mode is preferably adopted in which the filter can be removed and replaced separately from other components.

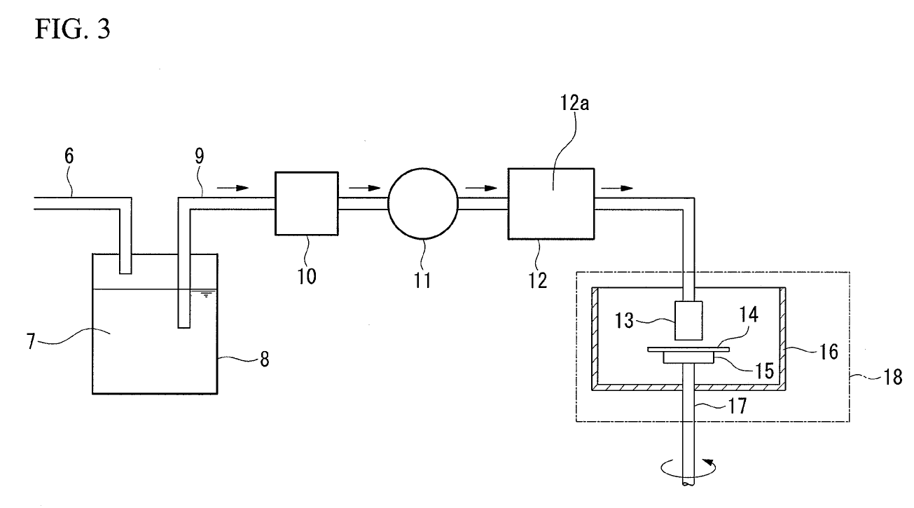

FIG. 3 shows a schematic illustration of one example of the applicator.

This applicator includes a storage unit 8 that stores the resist composition, a reservoir tank 10, a filtering unit (F1) 12 containing a filter (f1) 12a, and a coating unit 18.

A pressurization pipe 6 is provided in the storage unit 8. Accordingly, by pressurizing the resist composition 7 inside the storage unit 8 with an inert gas such as nitrogen, the resist composition 7 can be supplied from the storage unit 8 to the reservoir tank 10.

The coating unit 18 contains a nozzle 13, a support 15 for positioning the substrate, and a rotational axis 17, the tip of which is attached to the support 15. A closed-base cylindrical body 16 (a protective wall) is provided around the periphery of the nozzle 13 and the support 15, and the rotational axis 17 penetrates through the base of this cylindrical body. When the substrate 14 is rotated by rotating the support 15, the closed-base cylindrical body 16 prevents the resist composition on the substrate 14 from splattering.

This applicator can be used, for example, in the manner described below.

First, the resist composition 7 stored in the storage unit 8 is supplied from the storage unit 8, via an inlet pipe 9, to the reservoir tank 10. The resist composition is suctioned by a pump 11 and supplied to the first filtering unit 12, and is filtered by passage through the filter (f1) 12a provided inside the filtering unit (F1) 12. Having passed through the filtering unit (F1) 12, the resist composition is supplied from the nozzle 13 of the coating unit 18 onto the substrate 14 such as a silicon wafer or the like. By rotating the rotational axis 17 within the coating unit 18 during this process, the support 15 attached to the tip of the rotational axis 17 rotates the substrate 14 positioned on top of the support. The resulting centrifugal force causes the resist composition dripped onto the surface of the substrate 14 to spread outwards, thereby coating the surface of the substrate 14.

The reservoir tank 10 may be either included or excluded. Furthermore, there are no particular restrictions on the pump 11, provided it is capable of supplying the resist composition from the storage unit 8 to the coating unit 18.

Furthermore, a second filtering unit containing a filter (f2) may be provided prior to and/or after the filtering unit (F1) 12, and the specific combination of filters can be selected as desired from a variety of possible embodiments.

Furthermore, in the above description a spinner was described as one example of the applicator. However in recent years, a variety of non-rotational coating methods such as the slit nozzle method have been proposed, and because a variety of devices have been proposed for executing these methods, there are no particular restrictions on the coating method.

Furthermore, as mentioned above, the applicator may also be a so-called coater-developer in which the subsequent developing step is also conducted within the one device. An example of this type of device is the Clean Track ACT-8 (a product name), manufactured by Tokyo Electron Co., Ltd.

### [Resist Composition Used in the Above Process for Producing a Resist Composition]

A resist composition used in the above process for producing a resist composition is a so-called chemically amplified resist composition prepared by dissolving at least a component (A) and a component (B) in a component (S). In other words, the production process of the present invention is suited to treatment of this type of resist composition, and the filtering apparatus and applicator of the present invention are ideal devices for processing this type of resist composition.

Component (A)

There are no particular restrictions on the component (A), and one or more of the alkali-soluble resins, or resins that develop alkali solubility, which have been proposed as the base resins for conventional chemically amplified resists can be used. The former case describes a negative resist composition, and the latter case describes a positive resist composition.

In the case of a negative composition, the resist composition includes an alkali-soluble resin, the component (B), and a cross-linker. During resist pattern formation, when acid is generated from the component (B) by exposure, the action of this acid causes cross-linking between the alkali-soluble resin and the cross-linker, causing the resin to become insoluble in alkali.

As the cross-linker, a melamine that contains a methylol group or alkoxymethyl group, or an amino-based cross-linker such as urea or glycoluril or the like is usually used.

The blend quantity of the cross-linker is preferably within a range from 1 to 50 parts by weight per 100 parts by weight of the alkali-soluble resin.

In the case of a positive composition, the component (A) is an alkali-insoluble resin containing so-called acid-dissociable, dissolution-inhibiting groups. When acid is generated from the component (B) by exposure, this acid causes the acid-dissociable, dissolution-inhibiting groups to dissociate, making the resin component (A) alkali-soluble. As a result, during resist pattern formation, when a resist composition applied to the surface of a substrate is selectively exposed, the alkali solubility of the exposed portions increases, enabling alkali developing to be conducted.

Resist compositions applied to the process for producing a resist pattern according to the present invention are preferably positive compositions. The reason for this preference is that in the case of a positive composition, the fact that the component (A) contains acid-dissociable, dissolution-inhibiting groups means the composition is more prone to developing defects than a negative composition, and consequently the effects obtained upon application of the present invention are particularly dramatic.

Regardless of whether the composition is a positive or negative composition, the component (A) preferably contains structural units derived from (meth)acrylate esters. When such structural units are used in the production of a resist composition (and particularly a positive composition) that uses such a resin, the effect of the filter (f1) in removing the foreign matter that causes deterioration of the resist composition appears to improve, although the reason for this improvement is not entirely clear.

In this description, the term “(meth)acrylic acid” refers to acrylic acid and/or methacrylic acid. Furthermore, the term “structural unit” refers to a unit derived from a monomer that contributes to the formation of a polymer. The term “(meth)acrylate” refers to an acrylate and/or methacrylate.

In a resin containing structural units derived from (meth)acrylate esters, the proportion of these structural units within the component (A) is preferably at least 15 mol %, even more preferably 20 mol % or greater, and is most preferably 50 mol % or greater. There are no particular restrictions on the upper limit for this range, and a value of 100 mol % is also acceptable.

In the case of a positive resist composition, the component (A) is preferably a resin containing a structural unit (a1) derived from a (meth)acrylate ester that contains an acid-dissociable, dissolution-inhibiting group.

This resin may also optionally include the structural units (a2), (a3) and (a4) described below.

Structural unit (a2): a structural unit derived from a (meth)acrylate ester that contains a lactone ring.

Structural unit (a3): a structural unit derived from a (meth)acrylate ester that contains a hydroxyl group and/or a cyano group.

Structural unit (a4): a structural unit that cannot be classified as one of the above structural units (a1) through (a3), and is derived from a (meth)acrylate ester that contains an aliphatic polycyclic group.

Amongst positive resist compositions for use with an ArF excimer laser or radiation of an even shorter wavelength, most compositions include both the structural unit (a1) and the structural unit (a2). In a positive resist composition of this type, obtained by polymerizing monomers with different polarities, it is predicted that a variety of monomers, oligomers, and other by-products may cause defects and other foreign matter over time. The structural unit (a1) tends to have little polarity (exhibits large hydrophobicity), whereas the structural unit (a2) tends to develop a large polarity.

However, by applying the present invention, the quantity of foreign matter can be reduced and the level of defects suppressed, even for resist compositions that employ this type of resin prepared by polymerizing monomers with different polarities. Particularly in the case of positive resist compositions for use with an ArF excimer laser or radiation of an even shorter wavelength, defects such as the occurrence of fine scum or microbridges can be particularly problematic, and consequently application of the present invention is particularly effective.

Structural Unit (a1)

There are no particular restrictions on the acid-dissociable, dissolution-inhibiting group in the structural unit (a1). Typically, groups that form either a cyclic or chain-like tertiary alkyl ester with the carboxyl group of (meth)acrylic acid are the most widely known. Of these, aliphatic monocyclic or polycyclic group-containing acid-dissociable, dissolution-inhibiting groups are preferred. From the viewpoints of ensuring superior dry etching resistance and resist pattern formation, an aliphatic polycyclic group-containing acid-dissociable, dissolution-inhibiting group is particularly desirable.

Here, the term “aliphatic” is a relative concept used in relation to the term “aromatic”, and defines a group or compound or the like that contains no aromaticity. The term “aliphatic monocyclic group” describes a monocyclic group that contains no aromaticity, whereas the term “aliphatic polycyclic group” describes a polycyclic group that contains no aromaticity. In the following description, aliphatic monocyclic groups and aliphatic polycyclic groups may be referred to jointly as aliphatic cyclic groups. These aliphatic cyclic groups include both hydrocarbon groups (alicyclic groups) formed solely from carbon and hydrogen, and heterocyclic groups in which a portion of the carbon atoms that constitute the ring structure of the alicyclic group have been substituted with a hetero atom such as an oxygen atom, nitrogen atom, or sulfur atom. The aliphatic cyclic group is preferably an alicyclic group. The aliphatic cyclic group may be either saturated or unsaturated, although a saturated group is preferred, as such groups exhibit superior transparency to ArF excimer lasers and the like, and also exhibit excellent resolution and depth of focus (DOF).

Examples of aliphatic monocyclic groups include groups in which one hydrogen atom has been removed from a cycloalkane. Specific examples include groups in which one hydrogen atom has been removed from a monocycloalkane such as cyclohexane or cyclopentane.

Examples of aliphatic polycyclic groups include groups in which one hydrogen atom has been removed from a bicycloalkane, tricycloalkane or tetracycloalkane or the like. Specific examples include groups in which one hydrogen atom has been removed from a polycycloalkane such as adamantane, norbornane, isobornane, tricyclodecane or tetracyclododecane. These types of polycyclic groups can be selected appropriately from the multitude of groups proposed for use within the resin component of resist compositions for use with ArF excimer lasers and the like. Of the various possibilities, an adamantyl group, norbornyl group or tetracyclododecanyl group is preferred from an industrial viewpoint.

More specifically, the structural unit (a1) is preferably at least one unit selected from the general formulas (I), (II) and (III) shown below.

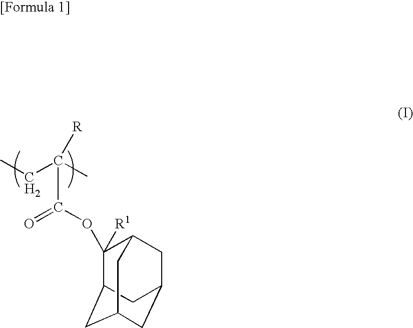

(wherein, R represents a hydrogen atom or a methyl group, and R¹ represents a lower alkyl group)

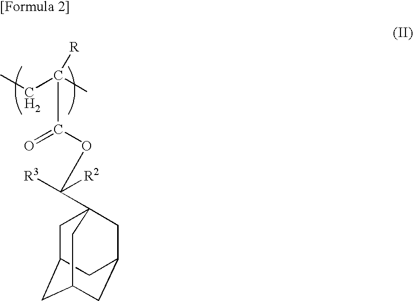

(wherein, R represents a hydrogen atom or a methyl group, and R² and R³ each represent, independently, a lower alkyl group)

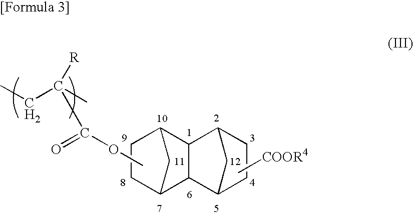

(wherein, R represents a hydrogen atom or a methyl group, and R⁴ represents a tertiary alkyl group)

In the formulas, R¹ is preferably a straight-chain or branched lower alkyl group of 1 to 5 carbon atoms, and specific examples include a methyl group, ethyl group, propyl group, isopropyl group, n-butyl group, isobutyl group, pentyl group, isopentyl group, and neopentyl group. Of these, an alkyl group of two or more carbon atoms, and particularly from 2 to 5 carbon atoms, is preferred, and such groups tend to produce increased acid dissociability compared with the case of a methyl group. From an industrial viewpoint, a methyl group or ethyl group is preferred.

The groups R² and R³ each preferably represent, independently, a lower alkyl group of 1 to 5 carbon atoms. These types of groups tend to exhibit a higher acid dissociability than a 2-methyl-2-adamantyl group. Specifically, the groups R² and R³ each preferably represent, independently, the same types of straight-chain or branched lower alkyl groups described above for R¹. Of these groups, the case in which R² and R³ are both methyl groups is preferred from an industrial viewpoint. A structural unit derived from 2-(1-adamantyl)-2-propyl(meth)acrylate is a specific example.

The group R⁴ preferably represents a tertiary alkyl group of 4 to 8 carbon atoms, a tertiary alkyl group of 4 to 5 carbon atoms such as a tert-butyl group or tert-amyl group is even more preferred, and a tert-butyl group is the most preferred industrially.

Furthermore, the group —COOR⁴ may be bonded to either position 3 or 4 of the tetracyclododecanyl group shown in the formula, although a mixture of both isomers results, and so the bonding position cannot be further specified. Furthermore, the carboxyl group residue of the (meth)acrylate structural unit may be bonded to either position 8 or 9 of the tetracyclododecanyl group, although similarly, the bonding position cannot be further specified.

Of the above possibilities, the structural unit (a1) is preferably a structural unit represented by the general formula (I) or (II), and is most preferably a structural unit represented by the formula (I).

The proportion of the structural unit (a1) within the component (A), relative to the combined total of all the structural units that constitute the component (A), is preferably within a range from 20 to 60 mol %, and is even more preferably from 30 to 50 mol %.

Structural Unit (a2)

Examples of the structural unit (a2) include structural units in which a monocyclic group formed from a lactone ring or a polycyclic group that includes a lactone ring is bonded to the ester side-chain portion of a (meth)acrylate ester. The term lactone ring refers to a single ring containing a —O—C(O)— structure, and this ring is counted as the first ring. Accordingly, in this description, the case in which the only ring structure is the lactone ring is referred to as a monocyclic group, and groups containing other ring structures are described as polycyclic groups regardless of the structure of the other rings.

Specific examples of the structural unit (a2) include monocyclic groups in which one hydrogen atom has been removed from γ-butyrolactone, and polycyclic groups in which one hydrogen atom has been removed from a lactone ring-containing polycycloalkane.

The structural unit (a2) is preferably a structural unit represented by one of the general formulas (IV) through (VII) shown below.

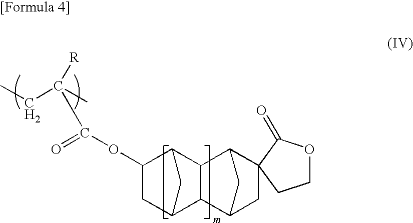

(wherein, R represents a hydrogen atom or a methyl group, and m represents 0 or 1)

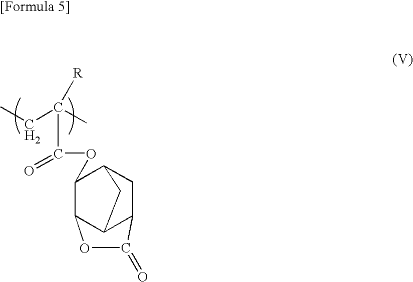

(wherein, R represents a hydrogen atom or a methyl group)

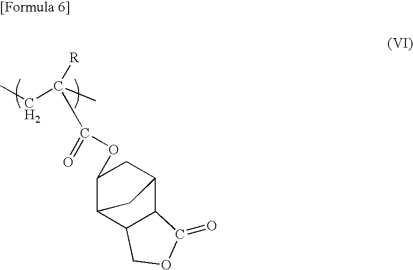

(wherein, R represents a hydrogen atom or a methyl group)

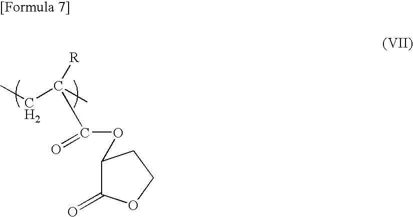

(wherein, R represents a hydrogen atom or a methyl group)

The proportion of the structural unit (a2) within the component (A), relative to the combined total of all the structural units that constitute the component (A), is preferably within a range from 20 to 60 mol %, and is even more preferably from 20 to 50 mol %.

Structural Unit (a3)

The structural unit (a3) can use a structural unit selected from the multitude of units proposed for use within the resin component of resist compositions for use with ArF excimer lasers and the like. For example, structural units that include a hydroxyl group and/or cyano group-containing aliphatic polycyclic group are preferred, and structural units that include a hydroxyl group or cyano group-containing aliphatic polycyclic group are particularly desirable.

These polycyclic groups can be selected appropriately from the same multitude of polycyclic groups exemplified above in relation to the structural unit (a1).

Specifically, the structural unit (a3) preferably includes a hydroxyl group-containing adamantyl group, cyano group-containing adamantyl group, or carboxyl group-containing tetracyclododecanyl group.

More specific examples include the structural units represented by a general formula (VIII) shown below.

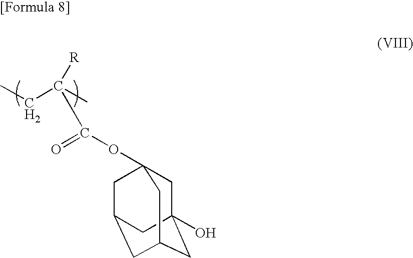

(wherein, R represents a hydrogen atom or a methyl group)

The proportion of the structural unit (a3) within the component (A), relative to the combined total of all the structural units that constitute the component (A), is preferably within a range from 10 to 50 mol %, and is even more preferably from 10 to 40 mol %.

Structural Unit (a4)

The polycyclic group in the structural unit (a4) can be selected from the same polycyclic groups exemplified above in relation to the structural unit (a1). For example, any of the multitude of conventional polycyclic groups proposed for use within the resin component of resist compositions for use with ArF excimer lasers or KrF excimer lasers (and preferably for ArF excimer lasers) can be used.

At least one group selected from amongst a tricyclodecanyl group, an adamantyl group, and a tetracyclododecanyl group is preferred in terms of factors such as industrial availability.

Specific examples of the structural unit (a4) include units of the structures (IX) to (XI) shown below.

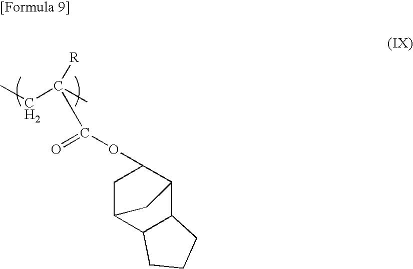

(wherein, R represents a hydrogen atom or a methyl group)

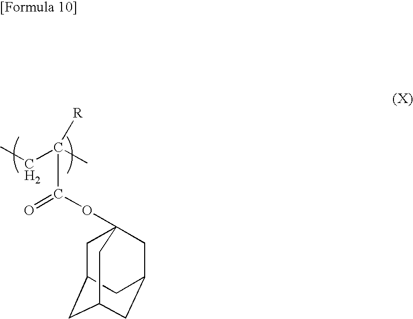

(wherein, R represents a hydrogen atom or a methyl group)

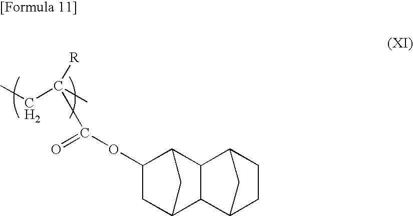

(wherein, R represents a hydrogen atom or a methyl group)

The proportion of the structural unit (a4) within the component (A), relative to the combined total of all the structural units that constitute the component (A), is preferably within a range from 1 to 25 mol %, and is even more preferably from 5 to 20 mol %.

The component (A) may also include other structural units besides the structural units (a1) to (a4) described above. As these other structural units, any structural unit that cannot be classified as one of the above structural units (a1) to (a4) can be used without any particular restrictions. Any of the multitude of conventional structural units proposed for use within the resin component of resist compositions for use with ArF excimer lasers or KrF excimer lasers (and preferably for ArF excimer lasers) can be used. In the present invention, the component (A) is preferably a copolymer that includes at least the structural unit (a1), the structural unit (a2) and/or the structural unit (a3), is preferably a copolymer that includes the structural units (a1), (a2) and (a3), and is most preferably a copolymer that includes all of the structural units (a1), (a2), (a3) and (a4).

A copolymer that includes a structural unit represented by the general formula (I), a structural unit represented by the general formula (V) or (VII), a structural unit represented by the general formula (VIII), and a structural unit represented by the general formula (IX) is particularly preferred, and copolymers formed solely from these four structural units are the most desirable.

The component (A) can be obtained, for example, by a conventional radical polymerization or the like of the monomers that yield each of the structural units, using a radical polymerization initiator such as azobisisobutyronitrile (AIBN).

Furthermore, —C(CF₃)₂—OH groups may be introduced at the terminals of the component (A) by also using a chain transfer agent such as HS—CH₂—CH₂—CH₂—C(CF₃)₂—OH during the above polymerization reaction. A resin wherein hydroxyalkyl groups in which a portion of the hydrogen atoms of the alkyl group have been substituted with fluorine atoms have been introduced in this manner is effective in reducing the levels of defects and LER (line edge roughness: non-uniform irregularities within the line side walls).

Although there are no particular restrictions on the weight average molecular weight (Mw) (the polystyrene equivalent value determined using gel permeation chromatography) of the component (A), the molecular weight value is preferably within a range from 5,000 to 30,000, and is even more preferably from 8,000 to 20,000. Provided the molecular weight is lower than the upper limit of this range, the level of solubility within resist solvents is adequate for use within a resist, whereas provided the molecular weight is larger than the lower limit of the above range, favorable levels of dry etching resistance and a favorable cross-sectional shape for the resist pattern can be obtained.

Furthermore, the degree of dispersion (Mw/Mn) is preferably within a range from 1.0 to 5.0, even more preferably from 1.0 to 3.0, and is most preferably from 1.2 to 2.5.

The component (A) may include either a single resin or a combination of two or more different resins. For example, one or more resins containing the types of structural units derived from (meth)acrylate esters described above may be used, or a mixture that also contains one or more other resins may also be used.

Component (B)

As the component (B), any of the known acid generators used within conventional chemically amplified resist compositions can be used without any particular restrictions. Examples of these acid generators are numerous, and include onium salt-based acid generators such as iodonium salts and sulfonium salts, oxime sulfonate-based acid generators, diazomethane-based acid generators such as bisalkyl or bisaryl sulfonyl diazomethanes and diazomethane nitrobenzyl sulfonates, iminosulfonate-based acid generators, and disulfone-based acid generators.

Specific examples of suitable onium salt-based acid generators include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, and diphenylmonomethylsulfonium trifluoromethanesulfonate, heptafluoropropanesulfonate or nonafluorobutanesulfonate.

Specific examples of suitable oxime sulfonate-based acid generators include α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile. Of these, α-(methylsulfonyloxyimino)-p-methoxyphenyl acetonitrile is preferred.

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

The component (B) may use either a single acid generator, or a combination of two or more different acid generators.

The quantity used of the component (B) is typically within a range from 0.5 to 30 parts by weight, and preferably from 1 to 10 parts by weight, per 100 parts by weight of the component (A). Provided the proportion of the component (B) falls within this numerical range, satisfactory pattern formation can be achieved, and a uniform solution can also be obtained, thereby enabling a suppression of factors that may cause a deterioration in the storage stability.

Component (S)

The component (S) may be any solvent capable of dissolving the various components used to generate a uniform solution, and one or more solvents selected from known materials used as the solvents for conventional chemically amplified resists can be used.

Examples of the solvent include lactones such as γ-butyrolactone; ketones such as acetone, methyl ethyl ketone, cyclohexanone, methyl isoamyl ketone and 2-heptanone; polyhydric alcohols and derivatives thereof such as ethylene glycol, diethylene glycol, propylene glycol, and dipropylene glycol; polyhydric alcohol derivatives including compounds with an ester linkage such as ethylene glycol monoacetate, diethylene glycol monoacetate, propylene glycol monoacetate and dipropylene glycol monoacetate, and compounds with an ether linkage such as the monomethyl ether, monoethyl ether, monopropyl ether, monobutyl ether or monophenyl ether of any of the above polyhydric alcohols or the above compounds with an ester linkage; cyclic ethers such as dioxane; and esters such as methyl lactate, ethyl lactate (EL), methyl acetate, ethyl acetate, butyl acetate, methyl pyruvate, ethyl pyruvate, methyl methoxypropionate, and ethyl ethoxypropionate.

These organic solvents may be used either alone, or as a mixed solvent containing two or more different solvents.

Of these solvents, propylene glycol monomethyl ether acetate (PGMEA), propylene glycol monomethyl ether (PGME), and EL are preferred.

Furthermore, mixed solvents produced by mixing PGMEA with a polar solvent are also preferred. Although the blend ratio (weight ratio) in such mixed solvents can be set in accordance with factors such as the co-solubility of the PGMEA and the polar solvent, the ratio is preferably within a range from 1:9 to 9:1, and is even more preferably from 2:8 to 8:2.

More specifically, in those cases where EL is added as the polar solvent, the weight ratio PGMEA:EL is preferably within a range from 1:9 to 9:1, and is even more preferably from 2:8 to 8:2. Furthermore, in those cases where PGME is used as the polar solvent, the weight ratio PGMEA:PGME is preferably within a range from 1:9 to 9:1, even more preferably from 2:8 to 8:2, and is most preferably from 3:7 to 7:3.

Furthermore, as the component (S), mixed solvents containing at least one of PGMEA and EL, together with γ-butyrolactone, are also preferred. In such cases, the weight ratio of the former and latter components in the mixed solvent is preferably within a range from 70:30 to 95:5.

There are no particular restrictions on the quantity used of the component (S), although in those cases where the resist composition is produced as a final product, the quantity should be set in accordance with the coating film thickness required, at a concentration that enables favorable application of the solution to a substrate or the like. Typically the quantity of the component (S) is set so that the solid fraction concentration of the resist composition is within a range from 2 to 20% by weight, and preferably from 5 to 15% by weight.

Optional Components

In the resist composition, in order to improve the resist pattern shape and the post exposure stability of the latent image formed by the pattern-wise exposure of the resist layer, a nitrogen-containing organic compound (D) (hereafter referred to as the component (D)) may be added as an optional component.

A multitude of these components (D) have already been proposed, and any of these known compounds can be used. However, an aliphatic amine, and particularly a secondary aliphatic amine or tertiary lower aliphatic amine is preferred. Examples of these aliphatic amines include amines in which at least one hydrogen atom of ammonia NH₃ has been substituted with an alkyl group or hydroxyalkyl group of 1 to 12 carbon atoms (that is, alkylamines or alkyl alcohol amines). Specific examples of these aliphatic amines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine; and alkyl alcohol amines such as diethanolamine, triethanolamine, diisopropanolamine, triisopropanolamine, di-n-octanolamine, and tri-n-octanolamine.

Of these, alkyl alcohol amines and trialkyl amines are preferred, and alkyl alcohol amines are the most desirable. Amongst the various alkyl alcohol amines, triethanolamine and triisopropanolamine are the most preferred.

These compounds may be used either alone, or in combinations of two or more different compounds.

The component (D) is typically used in a quantity within a range from 0.01 to 5.0 parts by weight per 100 parts by weight of the component (A).

Furthermore, in order to prevent any deterioration in sensitivity, and improve the resist pattern shape and the post exposure stability of the latent image formed by the pattern-wise exposure of the resist layer, an organic carboxylic acid, or a phosphorus oxo acid or derivative thereof (E) (hereafter referred to as the component (E)) may also be added to the resist composition as another optional component.

Examples of suitable organic carboxylic acids include malonic acid, citric acid, malic acid, succinic acid, benzoic acid, and salicylic acid.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate, and dibenzyl phosphonate; and phosphinic acid or derivatives thereof such as esters, including phosphinic acid and phenylphosphinic acid.

When added, the component (E) is typically used in a quantity within a range from 0.01 to 5.0 parts by weight per 100 parts by weight of the component (A).

Other miscible additives can also be added to the resist composition according to need, and examples include additive resins for improving the performance of the resist film, surfactants for improving the coating properties, dissolution inhibitors, plasticizers, stabilizers, colorants, halation prevention agents, and dyes and the like.

### [Resist Composition Obtained Using the Process for Producing a Resist Composition According to the Present Invention]

In a resist composition obtained in the manner described above, the occurrence of defects is suppressed, so that the occurrence of scum or microbridges in the developed resist pattern is less likely. Furthermore, the foreign matter characteristics of the composition are also excellent, with the composition containing a minimal quantity of foreign matter. Furthermore, the storage stability as a resist solution is also excellent, with favorable suppression of foreign matter generation during storage, and consequently excellent storage stability. As a result, a resist pattern formed using the above resist composition has a reduced level of defects.

Moreover, the resist composition obtained in the manner described above displays minimal change in the makeup of the composition before and after the filtering treatment.

As a result, the stability in the size of the resist patterns formed using the above resist composition is also excellent.

For the above resist composition, the level of defects, the foreign matter characteristics, and the storage stability as a resist solution can be evaluated, for example, using the methods described below.

The level of defects within a resist pattern can be evaluated in terms of the number of so-called surface defects, which can be detected using a surface defect inspection apparatus KLA2132 (a product name) manufactured by Tencor Corporation. Furthermore, a determination as to whether a defect is scum or a microbridge can be made on the basis of observation using a measuring SEM (scanning electron microscope) or the like.

The foreign matter characteristics and the storage stability as a resist solution can be evaluated by using a particle counter to measure the number of foreign matter particles. For example, the foreign matter characteristics can be evaluated by using a liquid particle counter (product name: Particle Sensor KS-41 or KL-20K, manufactured by Rion Co., Ltd.) to measure the resist composition immediately following completion of the filtering treatment. Furthermore, the storage stability as a resist solution is evaluated in the same manner as the foreign matter characteristics, by measuring samples that have been stored in a freezer, a refrigerator, or at room temperature (25° C.).

In a particle counter, the number of particles with a particle size within a range from 0.15 μm to 0.3 μm or greater is counted per 1 cm³ of composition. The measurement limit is typically approximately 20,000 particles/cm³. Specifically, the aforementioned Particle Sensor KS-41 can be used to measure the number of particles of particle size 0.15 μm or greater.

An evaluation of whether or not the makeup of the resist composition changes can be performed by analyzing and comparing the respective concentration values for the materials within the resist composition prior to, and then following, passage through the filter, and by measuring any changes in the sensitivity (optimum exposure dose) or the resist pattern size when forming a resist pattern using the photoresist composition.

### [Method of Forming Resist Pattern]

A method of forming a resist pattern using the resist composition obtained in the manner described above can be conducted, for example, in the manner described below.

First, the resist composition is applied to a substrate such as a silicon wafer using a spinner or the like, a prebake is then conducted under temperature conditions of 80 to 150° C., for a period of 40 to 120 seconds, and preferably for 60 to 90 seconds, and following selective exposure through a desired mask pattern using an ArF exposure apparatus or the like, PEB (post exposure baking) is conducted under temperature conditions of 80 to 150° C., for a period of 40 to 120 seconds, and preferably for 60 to 90 seconds. Subsequently, developing is conducted using an alkali developing solution such as a 0.1 to 10% by weight aqueous solution of tetramethylammonium hydroxide. In this manner, a resist pattern that is faithful to the mask pattern can be obtained.

An organic or inorganic anti-reflective film may also be provided between the substrate and the applied layer of the resist composition.

Furthermore, there are no particular restrictions on the wavelength used for the exposure, and an ArF excimer laser (193 nm), KrF excimer laser (248 nm), F₂ excimer laser (157 nm), or other radiation such as EUV (extreme ultra violet), VUV (vacuum ultra violet), EB (electron beam), X-ray or soft X-ray radiation can be used.

### EXAMPLES

As follows is a more detailed description of the present invention based on a series of examples.

The properties of the resist compositions produced in the following examples and comparative examples were determined using the methods described below.

### (1) Defects

First, an organic anti-reflective film composition AR-19 (a product name, manufactured by Shipley Co., Ltd.) was applied to the surface of a silicon wafer using a spinner, and was then dried on a hotplate at 215° C. for 60 seconds, thereby forming an organic anti-reflective film with a film thickness of 82 nm. The prepared resist composition was then applied to the surface of the anti-reflective film using a spinner, and was then prebaked (PAB (post applied bake)) and dried on a hotplate at 120° C. for 90 seconds, forming a resist layer with a film thickness of 360 nm on top of the anti-reflective film.

Subsequently, this layer was selectively irradiated with an ArF excimer laser (193 nm) through a mask pattern, using an ArF exposure apparatus NSR-S302A (manufactured by Nikon Corporation, NA (numerical aperture)=0.60, ⅔ annular illumination).

The irradiated resist was then subjected to PEB treatment at 120° C. for 90 seconds, subsequently subjected to puddle development for 60 seconds at 23° C. in a 2.38% by weight aqueous solution of tetramethylarumonium hydroxide, and was then washed for 20 seconds with water, and dried, thus forming a line and space (L/S) pattern with target dimensions of 130 nm.

The number of defects within this resist pattern was then measured using a surface defect inspection apparatus KLA2132 (a product name) manufactured by KLA Tencor Corporation, by evaluating the number of defects on the wafer. Three wafers were tested in each of the examples and comparative examples, and the average value was determined in each case.

In each of the examples and comparative examples, inspection of the defects using a measuring SEM S-9220 (manufactured by Hitachi, Ltd.) revealed that in all of the examples and comparative example, the defects were so-called bridge type defects, wherein adjacent line patterns had linked via a bridge type structure.

### Example 1

100 parts by weight of a copolymer (a-1) represented by a formula (a-1) shown below as the component (A), 3.5 parts by weight of triphenylsulfonium nonafluorobutanesulfonate as the component (B), 0.3 parts by weight of triethanolamine as the component (D), 25 parts by weight of γ-butyrolactone, and sufficient quantity of a mixed solvent of PGMEA:PGME=6:4 (weight ratio) to generate a solid fraction concentration within the resulting composition of 9% by weight were mixed together and dissolved, thus preparing a positive resist composition.

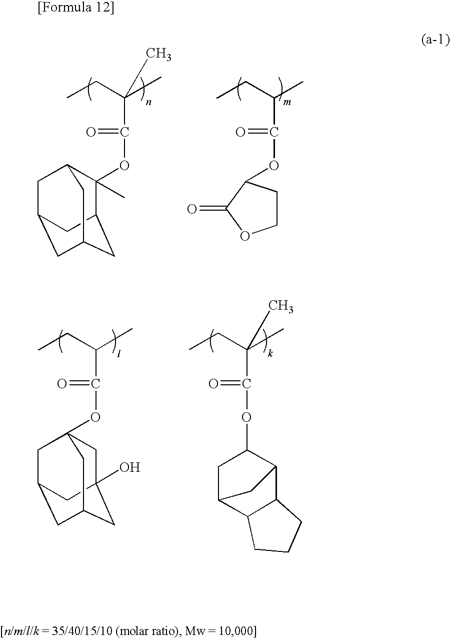

A polyethylene hollow thread membrane filter described below was installed as the second filter 4a within the second filtering unit 4 of the filtering apparatus shown in FIG. 1, and 2,000 ml of the above resist composition was then supplied directly from the storage tank 1 to the second filtering unit 4, and filtered through the polyethylene hollow thread membrane of the second filter 4a provided within the second filtering unit 4, yielding a resist composition.

The filtration pressure for the resist composition supplied to the second filtering unit 4 was set to 0.3 kgf/cm².

Polyethylene hollow thread membrane filter: a sample filter obtained from KITZ Corporation, with a pore size of 0.02 μm, and specifications including a filtration pressure [differential pressure resistance (25° C.)] of 0.4 MPa and a surface area (filtration area) of 3,000 cm. The filter was a disposable type filter with dimensions of diameter: 50 mm×height: 15 cm.

The resist composition obtained above was stored at room temperature (23° C.) for one month, and when the above evaluation was then conducted, the quantity of defects was 78 per wafer.

### Comparative Example 1

With the exception of using the polypropylene hollow thread membrane filter described below as the second filter 4a, a resist composition was prepared and evaluated in the same manner as the example 1.

Polypropylene hollow thread filter: product name “Unipore Polyfix” (manufactured by KITZ Corporation, with a pore size of 0.02 μm, and specifications including a filtration pressure [differential pressure resistance (20° C.)] of 0.4 MPa and a surface area (filtration surface area) of 3,400 cm². The filter was a disposable type filter with dimensions of diameter: 58 mm×height: 148.6 mm. The critical surface tension was 29 dyne/cm.)

The evaluation result revealed 315 defects per wafer.

### Comparative Example 2

With the exception of using the polyethylene flat membrane filter described below as the second filter 4a, a resist composition was prepared and evaluated in the same manner as the example 1.

Polyethylene flat membrane filter: product name “Microguard UPE filter” (manufactured by Mykrolis Corporation, pore size: 0.02 μm, the filtration pressure was set in accordance with the filter. The critical surface tension was 31 dyne/cm.)

The evaluation result revealed 9,134 defects per wafer.

### Comparative Example 3

With the exception of using the polyethylene flat membrane filter described below as the second filter 4a, a resist composition was prepared and evaluated in the same manner as the example 1.

Polyethylene flat membrane filter: product name “Microguard UPE filter” (manufactured by Mykrolis Corporation, pore size: 0.01 μm, the filtration pressure was set in accordance with the filter. The critical surface tension was 31 dyne/cm.)

The evaluation result revealed 489 defects per wafer.

The results for the example 1 and the comparative examples 1 to 3 are shown in Table 1. In Table 1, PE represents polyethylene and PP represents polypropylene.

As shown in Table 1, in the example 1 that used a filter equipped with a polyethylene hollow thread membrane, the occurrence of defects was significantly suppressed.

In contrast, in the comparative example 1, which used a similar hollow thread membrane to the example 1 with an identical pore size but in which the membrane was formed from polypropylene, and the comparative example 2, which used a polyethylene filter that had the same pore size as the example but was a flat membrane type filter, the quantity of defects was greater than that observed for the example 1.

Furthermore, the quantity of defects in the example 1 was even lower than that for the comparative example 3, which used a flat membrane filter with a smaller pore size. From these results it is clear that a superior defect improvement effect can be obtained even when using a filter with a comparatively large pore size and a large processing capability, which yields an improvement in productivity.

TABLE 1

| | Defects (number) | | | |
|---|---|---|---|---|
| | 1 month at | Second filter 4a | | |
| | room temperature | Membrane type | Material | Pore size |
| Example 1 | 78 | Hollow thread membrane | PE | 0.02 μm |
| Comparative example 1 | 315 | Hollow thread membrane | PP | 0.02 μm |
| Comparative example 2 | 9134 | Flat membrane | PE | 0.02 μm |
| Comparative example 3 | 489 | Flat membrane | PE | 0.01 μm |

### Example 2

100 parts by weight of a copolymer (a-2) represented by a formula (a-2) shown below as the component (A), 2.0 parts by weight of triphenylsulfonium nonafluorobutanesulfonate as the component (B), 0.2 parts by weight of triethanolamine as the component (D), 25 parts by weight of γ-butyrolactone, and sufficient quantity of PGMEA to generate a solid fraction concentration within the resulting composition of 9% by weight were mixed together and dissolved, thus preparing a positive resist composition.

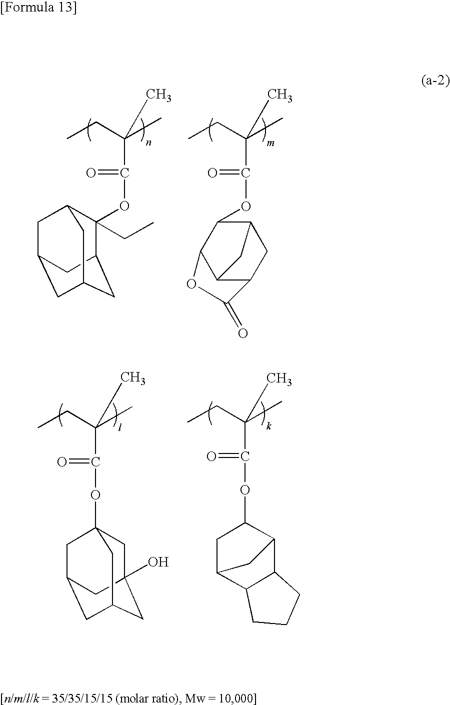

A nylon flat membrane filter described below was installed as the first filter 2a within the first filtering unit 2 of the filtering apparatus shown in FIG. 1, and a polyethylene hollow thread membrane filter described below was installed as the second filter 4a within the second filtering unit 4, and 4,000 ml of the above resist composition was then supplied from the storage tank 1 to the first filtering unit 2, and was then filtered sequentially through the first filter 2a and the second filter 4a, thus yielding a resist composition.

The filtration pressure for the resist composition supplied to the first filtering unit 2 and the second filtering unit 4 was set to 0.4 kgf/cm.

Nylon flat membrane filter: product name “Ultipore N66 ” (manufactured by Pall Corporation, pore size: 0.04 μm, zeta potential: −15 mV. The specifications included a filtration pressure [differential pressure resistance (38° C.)] of 4.2 kgf/cm², and a surface area (filtration area) of 0.09 m². The filter was a disposable type filter with dimensions of diameter: 72 mm×height: 114.5 mm. The critical surface tension was 77 dyne/cm.

Polyethylene hollow thread membrane filter: a sample filter obtained from KITZ Corporation (with a pore size of 0.02 μm, and specifications including a filtration pressure [differential pressure resistance (20° C.)] of 0.4 MPa and a surface area (filtration area) of 3,400 cm². The filter was a disposable type filter with dimensions of diameter: 58 mm×height: 148.6 mm. The critical surface tension was 29 dyne/cm.)

The resist composition obtained above was stored at 40° C. for two weeks, and when the above evaluation was then conducted, the quantity of defects was 67 per wafer.

### Comparative Example 4

With the exception of using the polypropylene hollow thread membrane filter described below as the second filter 4a, a resist composition was prepared and evaluated in the same manner as the example 2.

Polypropylene hollow thread filter: product name “Unipore Polyfix” (manufactured by KITZ Corporation, with a pore size of 0.02 μm, and specifications including a filtration pressure [differential pressure resistance (20° C.)] of 0.4 MPa and a surface area (filtration surface area) of 3.400 cm². The filter was a disposable type filter with dimensions of diameter: 58 mm×height: 148.6 mm. The critical surface tension was 29 dyne/cm.)

The evaluation result revealed 207 defects per wafer.

### Comparative Example 5

With the exception of using the polyethylene flat membrane filter described below as the second filter 4a, a resist composition was prepared and evaluated in the same manner as the example 2.

Polyethylene flat membrane filter: product name “Microguard UPE filter” (manufactured by Mykrolis Corporation, pore size: 0.02 μm, the filtration pressure was set in accordance with the filter. The critical surface tension was 31 dyne/cm.)

The evaluation result revealed 346 defects per wafer.

The results for the example 2 and the comparative examples 4 to 5 are shown in Table 2. In Table 2, PE represents polyethylene and PP represents polypropylene.

As shown in Table 2, in the example 2 that used a filter equipped with a polyethylene hollow thread membrane, the occurrence of defects was significantly suppressed.

In contrast, in the comparative example 4, which used a similar hollow thread membrane to the example 2 with an identical pore size but in which the membrane was formed from polypropylene, and the comparative example 5, which used a polyethylene filter that had the same pore size as the example but was a flat membrane type filter, the quantity of defects was greater than that observed for the example 2.

TABLE 2

| | Defects (number) | | | |
|---|---|---|---|---|
| | Two weeks | Second filter 4a | | |
| | at 40° C. | Membrane type | Material | Pore size |
| Example 2 | 67 | Hollow thread membrane | PE | 0.02 μm |
| Comparative example 4 | 207 | Hollow thread membrane | PP | 0.02 μm |
| Comparative example 5 | 346 | Flat membrane | PE | 0.02 μm |

From the above results it is clear that in the examples according to the present invention, the level of defects was able to be improved dramatically by using a filter equipped with a polyethylene hollow thread membrane.

### INDUSTRIAL APPLICABILITY

According to the present invention, there are provided a process for producing a resist composition in which the occurrence of defects has been suppressed, a filtering apparatus that can be used favorably within the production process, a resist composition applicator that is fitted with the filtering apparatus, and a resist composition in which the level of defects has been suppressed. Accordingly, the present invention is extremely useful industrially.

1. A process for producing a resist composition, comprising a step (I) of passing a resist composition, which is obtained by dissolving a resin component (A) that displays changed alkali solubility under action of acid and an acid generator component (B) that generates acid upon exposure in an organic solvent (S), through a filter (f1) equipped with a polyethylene hollow thread membrane.

2. A process for producing a resist composition according to claim 1, further comprising a step, which is conducted prior to and/or following said step (I), of passing said resist composition through a filter equipped with a nylon membrane and/or a filter equipped with a fluororesin membrane.

3. A filtering apparatus comprising a filtering unit (F1), which has a filter (f1) equipped with a polyethylene hollow thread membrane and is provided within a flow path for a resist composition obtained by dissolving a resin component (A) that displays changed alkali solubility under action of acid and an acid generator component (B) that generates acid upon exposure in an organic solvent (S).

4. A filtering apparatus according to claim 3, further comprising a filtering unit (F2), which is positioned upstream and/or downstream from said filtering unit (F1) and comprises a filter equipped with a nylon membrane and/or a filter equipped with a fluororesin membrane.

5. A resist composition applicator that is fitted with a filtering apparatus according to claim 3.

6. A resist composition obtained using a process for producing a resist pattern according to claim 1.
